(19) United States
(12) Patent Application Publication
(10) Pub. No.: US 2016/0118273 A1
(43) Pub. Date: Apr. 28, 2016

(54) SEMICONDUCTOR PACKAGE AND METHOD OF MANUFACTURING THE SAME

(71) Applicant: Samsung Electronics Co., Ltd., Suwon-si (KR)

(72) Inventors: Yun-Hee CHO, Seoul (KR); Young-Bae KIM, Hwaseong-si (KR)

(21) Appl. No.: 14/824,079

(22) Filed: Aug. 12, 2015

(30) Foreign Application Priority Data
Oct. 22, 2014 (KR) 10-2014-0143519

(51) Int. Cl. H01L 21/56; H01L 21/78

(52) U.S. Cl. CPC H01L 21/565; H01L 21/78

(57) ABSTRACT

A method of manufacturing a semiconductor package includes providing a package substrate, arranging a plurality of semiconductor devices in an array pattern on an upper surface of the package substrate and electrically connecting the plurality of semiconductor devices to the package substrate, and forming a molding member on the upper surface of the package substrate to cover the semiconductor chips. The molding member includes a warpage-preventing portion configured to prevent or reduce a warpage of the package substrate. The warpage-preventing portion may be raised above a top surface of a base portion of the molding member.

CROSS-RELATED APPLICATION

This application claims priority under 35 USC § 119 to Korean Patent Application No. 10-2014-0143519, filed on Oct. 22, 2014 in the Korean Intellectual Property Office (KIPO), the contents of which are herein incorporated by reference in their entirety.

### BACKGROUND

1. Field

The present disclosure relates to a semiconductor package and a method of manufacturing the same.

2. Description of the Related Art

Generally, a semiconductor package may be manufactured by a process for arranging semiconductor chips on an upper surface of a package substrate, a process for forming a molding material on the package substrate, a process for annealing the molding material to form a molding member, a process for forming external terminals on a lower surface of the package substrate, etc.

According to related art, during the annealing process, the package substrate may be warped due to a difference between thermal expansion coefficients of the package substrate and the molding material. As a result, subsequent processes may not be properly performed on the warped semiconductor substrate.

### SUMMARY

Example embodiments provide a semiconductor package structure that may be capable of preventing or reducing a warpage of a package substrate.

Example embodiments also provide a method of manufacturing a semiconductor device using the above-mentioned semiconductor package structure.

According to exemplary embodiments, a method of manufacturing a semiconductor package includes providing a package substrate, arranging a plurality of semiconductor devices in an array pattern on an upper surface of the package substrate and electrically connecting the plurality of semiconductor devices to the package substrate, and forming a molding member on the upper surface of the package substrate to cover the semiconductor chips. The molding member includes a warpage-preventing portion configured to prevent or reduce a warpage of the package substrate. The warpage-preventing portion may be raised above a top surface of a base portion of the molding member.

In certain embodiments, the warpage-preventing portion is formed along a boundary lane between the semiconductor devices.

In certain embodiments, the base portion of the molding member is integrally formed with the warpage-preventing portion. For example, the base portion of the molding member and the warpage-preventing portion may be formed in a single process using a mold. In one embodiment, the molding member is formed by placing the mold over the package substrate, filling the mold with a mold material moving the mold, and performing a heating and annealing process on the mold material.

In certain embodiments, the warpage-preventing portion includes one or more support beams formed at a top of the molding member. The warpage-preventing portion may have a grid structure configured to surround each of the semiconductor devices.

In certain embodiments, the package substrate extends lengthwise and widthwise, the length being longer than the width, and the warpage-preventing portion comprises at least a first warpage-preventing line extending in the lengthwise direction of the package substrate. In addition, the warpage-preventing portion may further comprise at least a second warpage-preventing line extending in the widthwise direction of the package substrate.

In certain embodiments, the method further includes providing conductive connecting members electrically connected between the package substrate and the semiconductor devices.

The semiconductor devices may be semiconductor chips.

In certain embodiments, the warpage-preventing portion is formed at scribe regions of the package substrate. The method may additionally include singulating the semiconductor devices from each other to form a plurality of individual semiconductor packages. Singulation includes cutting the package substrate and molding member at the scribe regions to prevent the warpage-preventing portion from being included in the molding member of the individual semiconductor packages.

According to other exemplary embodiments, a method of manufacturing a semiconductor package includes arranging a plurality of semiconductor devices on an upper surface of a package substrate, electrically connecting the semiconductor devices with the package substrate, coating a molding material on the upper surface of the package substrate, annealing the molding material to form a molding member configured to cover the semiconductor devices, cutting the molding member along a scribe lane between the semiconductor devices, and removing the warpage-preventing portion in the process. The molding material includes a warpage-preventing portion configured to prevent or reduce a warpage of the package substrate.

In certain embodiments, the warpage-preventing portion includes at least a first raised portion raised above a top surface of a base portion of the molding material.

Coating the molding material may include forming the first raised portion in a lengthwise direction of the substrate. Coating the molding material may additionally include forming at least a second raised portion in a widthwise direction of the package substrate.

In certain embodiments, the warpage-preventing portion is integrally formed with the base portion to form the molding member.

According to another exemplary embodiment, a method of manufacturing a semiconductor device includes providing a package substrate, placing a plurality of semiconductor devices in an array pattern on the package substrate to form a semiconductor device structure, electrically connecting the plurality of semiconductor devices to the package substrate, forming a molding member on the package substrate, and singulating the plurality of semiconductor devices from each other to form a plurality of individual semiconductor packages. The molding member includes a base portion extending to a first height above a top surface of the substrate, and at least a first raised portion extending above a top of the base portion to a second height higher than the first height. The base portion is integrally formed with the first raised portion.

In certain embodiments, the first raised portion forms a support beam and is formed at a scribe region of the semiconductor device structure between semiconductor devices, and the method further includes singulating the plurality of semiconductor devices by cutting the molding member along a scribe region between the semiconductor devices, and removing at least the first raised portion in the process.

In certain embodiments, the first raised portion is part of a warpage-preventing portion configured to prevent or reduce warping during forming the plurality of semiconductor devices.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a perspective view illustrating a semiconductor package structure in accordance with example embodiments;

FIG. 2 is a plan view illustrating the semiconductor package structure in FIG. 1, according to one example embodiment;

FIG. 3a is a cross-sectional view taken along a line 3a-3a′ in FIG. 2, according to one example embodiment;

FIG. 3b is a cross-sectional view taken along a line 3b-3b′ in FIG. 2, according to one example embodiment;

FIGS. 4 to 7 are cross-sectional views illustrating an exemplary method of manufacturing a semiconductor package using the semiconductor package structure of FIG. 1;

FIG. 8 is a perspective view illustrating a semiconductor package structure in accordance with example embodiments;

FIG. 9 is a plan view illustrating the semiconductor package structure in FIG. 8, according to one example embodiment;

FIG. 10 is a cross-sectional view taken along a line 10-10′ in FIG. 9, according to one example embodiment; and

FIGS. 11 to 14 are cross-sectional views illustrating an exemplary method of manufacturing the semiconductor package structure in FIG. 9, according to one example embodiment.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, or as “contacting” another element or layer, there are no intervening elements or layers present. Like numerals refer to like elements throughout.

As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another region, layer or section, for example as a naming convention. Thus, a first element, component, region, layer or section discussed below in one section of the specification could be termed a second element, component, region, layer or section in another section of the specification or in the claims without departing from the teachings of the present disclosure. In addition, in certain cases, even if a term is not described using “first,” “second,” etc., in the specification, it may still be referred to as “first” or “second” in a claim in order to distinguish different claimed elements from each other.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present disclosure.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

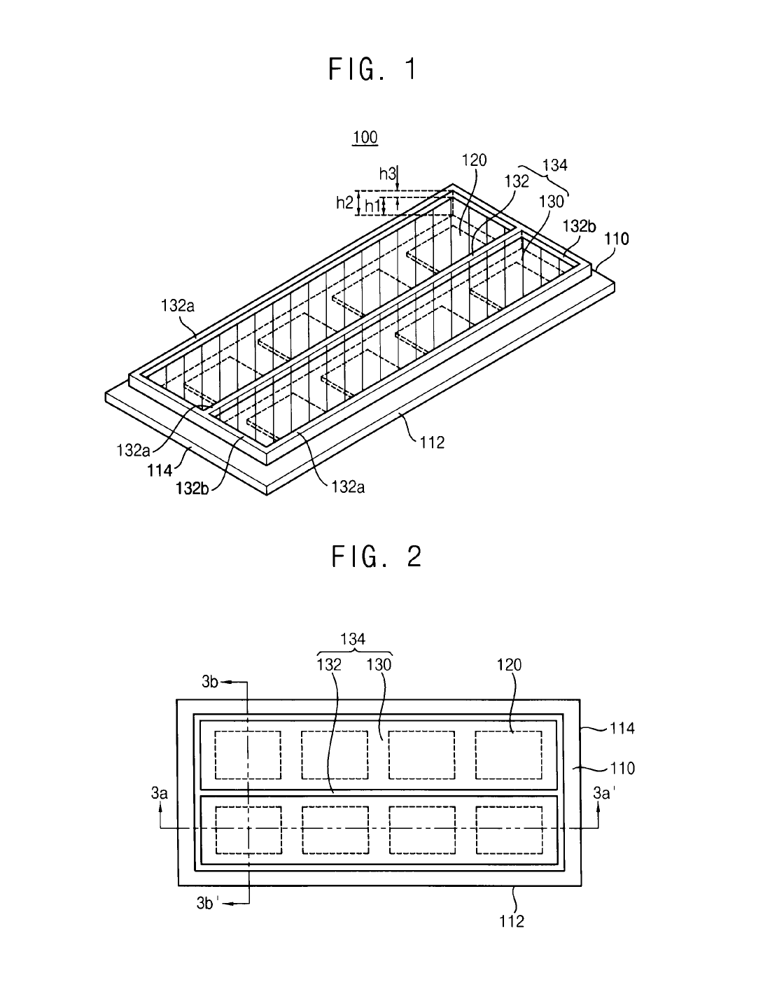

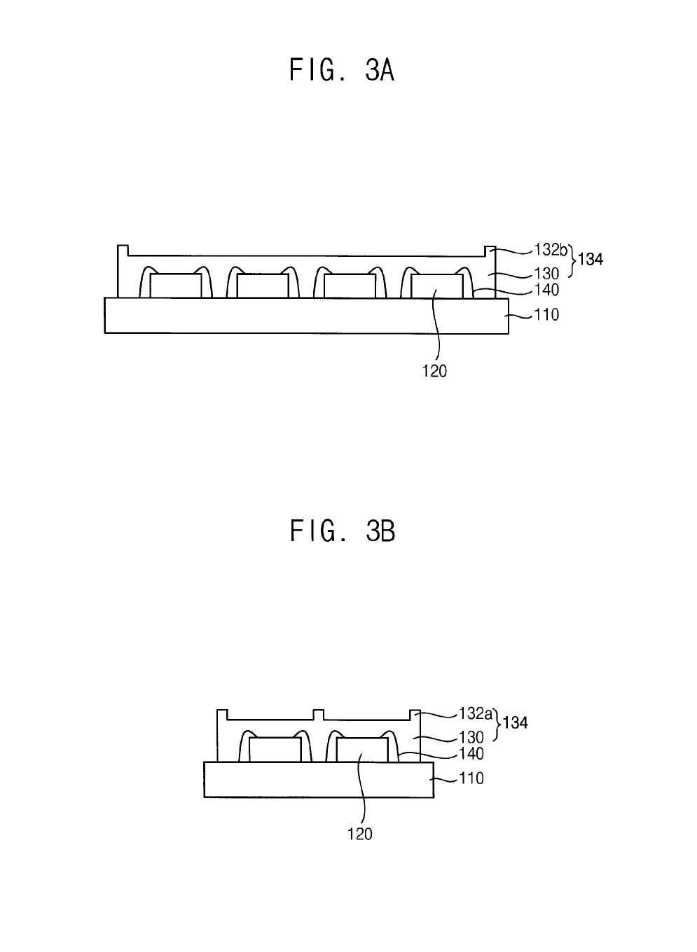

FIG. 1 is a perspective view illustrating a semiconductor package structure in accordance with example embodiments, FIG. 2 is a plan view illustrating the semiconductor package structure in FIG. 1, and FIGS. 3a and 3b are a cross-sectional views taken along the lines 3a-3a′ and 3b-3b′ respectively in FIG. 2, according to one example embodiment.

Referring to FIGS. 1 to 3, a semiconductor package structure 100 of this example embodiment may include a package substrate 110, a plurality of semiconductor devices 120, conductive connecting members 140 and a molding member 134.

The package substrate 110 may include, for example, an insulating substrate and conductive patterns formed in the insulating substrate. Each of the conductive patterns may include an upper end exposed through an upper surface of the insulating substrate, and a lower end exposed through a lower surface of the insulating substrate. These upper and lower ends may form terminals, and in certain embodiments, may include pads, bumps, or other conductive terminals. In one embodiment, the package substrate 110 may have a rectangular parallelepiped shape. Thus, the package substrate 110 may have a long side surface 112 and a short side surface 114. As such, the package substrate 110 may extend in a lengthwise direction, and may extend in a widthwise direction, wherein the length is greater than the width. Alternatively, the package substrate 110 may have other shapes as well as the rectangular parallelepiped shape. For example, the package substrate 110 may have a square shape having four side surfaces that may have substantially the same length.

The semiconductor devices 120 may include semiconductor chips. For example, each semiconductor device 120 may be a single semiconductor chip that includes an integrated circuit on a die. In addition, each semiconductor device 120 may include a stack of semiconductor chips, may include a semiconductor package, or may include a stack of semiconductor packages that form a package-on-package device. The semiconductor devices 120 may be arranged on the upper surface of the package substrate 110. In one embodiment, the semiconductor devices 120 may be attached to the upper surface of the package substrate 110 using an adhesive. For ease of description, below descriptions refer to the semiconductor devices 120 as semiconductor chips. However, aspects of the various embodiments described below may apply when the semiconductor devices 120 are stacks of semiconductor chips, packages, or package-on-package devices.

In one embodiment, each of the semiconductor chips 120 may include bonding pads. The bonding pads may be arranged on an edge portion of an upper surface of each of the semiconductor chips 120. In one embodiment in the case where the semiconductor devices 120 are packages, the bonding pads may be arranged on an edge portion of an upper surface of a package substrate of the package. In one embodiment, the semiconductor chips 120 may be arranged on the upper surface of the package substrate 110 in an array pattern. The semiconductor chips 120 may be arranged on the upper surface of the package substrate 110 by substantially the same interval. A boundary lane between the semiconductor chips 120 may correspond to a scribe lane of the package substrate 110. The scribe lane, also referred to as a scribe region, may be a region where the communication circuitry of the package substrate 110 is not formed, or a region that when cut through, does not affect communications of signals transmitted to, from, or within the package substrate 110. The scribe lane of the package substrate 110 may be cut to singulate the semiconductor chips 120 and to form individual semiconductor packages.

The conductive connecting members 140 may electrically connect the bonding pads of the semiconductor chips 120 with the conductive patterns of the package substrate 110. In example embodiments, the conductive connecting members 140 may include conductive wires electrically connected between the bonding pads of the semiconductor chips 120 and the conductive patterns of the package substrate 110. The conductive connecting members 140 may electrically connect the semiconductor chips 120 to the package substrate 110. For example, these conductive connecting members 140 may pass signals between the semiconductor chips 120 and the package substrate 110, and may also be referred to as conductive interconnections. Alternatively, the conductive connecting members 140 may include conductive bumps. For example, a flip chip configuration may be used where the conductive bumps are arranged on a lower surface of each of the semiconductor chips 120. The conductive bumps may be arranged between the bonding pads of the semiconductor chips 120 and the upper surface of the package substrate 110. In this embodiment, the use of a separate adhesive layer may be omitted, as the conductive bumps may function as the adhesive. In yet another embodiment, through substrate vias may be used to electrically connect the semiconductor chips 120 to the package substrate.

The molding member 134 may be formed on the upper surface of the package substrate 110 to cover the semiconductor chips 120. The molding member 134 may be formed by coating a molding material on the upper surface of the package substrate 110, and by annealing the molding material. The molding material may have a thermal expansion coefficient higher than a thermal expansion coefficient of the package substrate 110. Thus, the molding material may be expanded more than the package substrate 110 during the annealing process. Further, the molding material may be contacted more than the package substrate 110 during the annealing process. As a result, because the molding material may be contracted more than the package substrate 110 during the annealing process, the package substrate 110 connected to the molding material may be downwardly warped (e.g., such that it has a convex shape facing toward a surface below the package substrate 110).

In example embodiments, the molding member 134 may include a base portion 130 and a warpage-preventing portion 132. The base portion 130 may be formed to extend upward from the top surfaces of the package substrate 110 and semiconductor chips 120 to a first height (e.g., h1) above the surface of the package substrate 110. Thus, the base portion 130 may have a first height h1. The warpage-preventing portion 132, also referred to as a warpage-controlling portion, or a warpage-reducing portion, may have a grid-like shape, and may include certain bar-shaped or ridge-shaped parts. The warpage-preventing portion 132 may extend from the first height h1 to a second height h2 above the top surface of the substrate 110, and may thus have a third height h3. In certain embodiments, the warpage-preventing portion 132 is configured to prevent or reduce a warpage of the package substrate 110. The warpage-preventing portion 132 may be arranged at a portion of the molding member 134 corresponding to the scribe lane of the package substrate 110. Thus, the warpage-preventing portion 132 may be arranged along the boundary lane of the semiconductor chips 120. As mentioned above, because the scribe lane of the package substrate 110 may be removed by the cutting process, the warpage-preventing portion 132 may also be removed by the cutting process.

Therefore, the final semiconductor packages formed from the semiconductor package structure 100 may not include the warpage-preventing portion 132.

The warpage-preventing portion 132 may suppress expansion and contraction of the molding member 134 (particularly of the base portion 130 of the molding member 134) to prevent the warpage of the package substrate 110. In one embodiment, the warpage-preventing portion 132 may be integrally formed with the base portion 130 to form the molding member 134. For example, the warpage-preventing portion 132 may be integrally formed with the base portion 130 of the molding member 134 by the molding process, not by an additional process. As such, the base portion 130 and warpage-preventing portion 132 may be formed of the same material in the same molding process, to form a single-piece molding member 134. Thus, additional processes for forming the warpage-preventing portion 132 may not be needed.

The possible warpage of the package substrate 110 may be spread along the long side surface 112 and the short side surface 114 of the package substrate 110 (e.g., in a lengthwise and widthwise direction). Particularly, in certain embodiments, the package substrate 110 may be more prone to warpage along the long side surface 112 of the package substrate 110 relatively than the short side surface 114 of the package substrate 110. Thus, the warpage-preventing portion 132 may include first warpage-preventing lines 132a. These first warpage-preventing lines 132a, also referred to generally as first warpage-preventing parts, may be extended along the lengthwise direction (e.g., long side surface 112) of the package substrate 110. The first warpage-preventing lines 132a may reinforce strength of the molding member 134 along the long side surface 112 of the package substrate 110 to suppress the expansion and the contraction of the molding member 134. As such, the warpage-preventing lines 132a may form support beams, configured to prevent or reduce warping or bending of the molding member 134. The warpage of the package substrate 110 along the long side surface 112 may be prevented or reduced by the first warpage-preventing lines 132a. The first warpage-preventing lines 132a may have a height and a thickness that are determined based on the expected warpage of the package substrate 110. For example, if greater warpage is expected, then a mold can be used that causes the warpage-preventing lines 132 to have a greater height h2 and/or a greater thickness.

Though the package substrate 110 may be more prone to warpage in a lengthwise direction, the warpage-preventing portion 132 may additionally include second warpage-preventing lines 132b, that extend in a widthwise direction along the package substrate 110. These may assist in preventing warpage in the widthwise direction.

As can be seen in FIGS. 1, 2, 3a, and 3b, to assist in preventing or reducing warpage during the formation of a molding member on a semiconductor device, the molding member may include certain raised portions raised above the majority surface of the molding member. These raised portions may protrude from a top surface of the molding member. They may be formed on a top of a base portion of the molding member. For example, in one embodiment, above the region where semiconductor device are disposed, the molding member may extend to a first height above the top surface of the package substrate (e.g., h1). Above a scribe region, the molding member may extend to a second height above the top surface of the package substrate (e.g., h2). The second height may be higher than the first height. The raised portions of the molding member may have different parts that extend in different directions. For example, first raised lines 132a may extend in a first direction (e.g., a lengthwise direction), and second raised lines 132b may extend in a second direction (e.g., a widthwise direction). The different parts of the raised portions may have, for example, bar shapes, and when considered together may form a grid pattern.

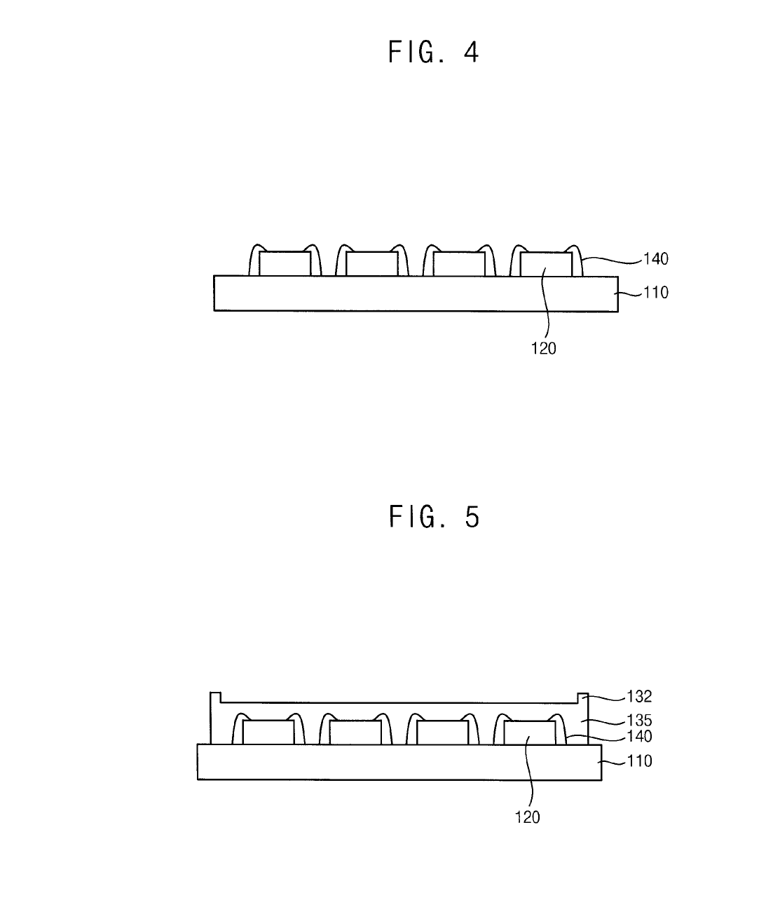

FIGS. 4 to 7 are cross-sectional views illustrating an exemplary method of manufacturing a semiconductor package using the semiconductor package structure in FIG. 1.

Referring to FIG. 4, a package substrate 110 and a plurality of semiconductor devices, such as semiconductor chips 120 may be provided. The semiconductor chips 120 may be attached to the upper surface of the package substrate 110. The semiconductor chips 120 may be arranged by the substantially the same interval. Thus, the scribe lane of the package substrate 110 may be formed between the semiconductor chips 120. As discussed above, though semiconductor chips 120 are given as examples, each semiconductor device 120 may be a single semiconductor chip, a stack of semiconductor chips, a semiconductor package, or a package-on-package device.

The conductive wires 140, or other conductive interconnections in different embodiments, may be electrically connected between the semiconductor chips 120 and the package substrate 110. The conductive wires 140 may electrically connect the bonding pads of the semiconductor chips 120 with the conductive patterns of the package substrate 110. Alternatively, the semiconductor chips 120 may be electrically connected with the package substrate 110 using the conductive bumps (e.g., in a flip-chip manner), or in other ways. A bonding procedure may be performed to connect the conductive wires 140 to the semiconductor chips 120 and the package substrate 110.

Referring to FIG. 5, the package substrate 110 with the semiconductor chips 120 may be positioned in a cavity of a mold. The mold may include certain grooves configured to form the ridges that form a warpage-preventing portion 132 such as described above. For example, the mold may include one or more first grooves for forming one or more first warpage-preventing lines 132a. Thus, the first grooves may be formed on an upper surface of the cavity of the mold along the long side surface 112 of the package substrate 110. Though FIGS. 1, 2, 3a, and 3b describe an example where only three raised lines 132a are shown, these examples are not intended to limit the scope of the inventive concept. For example, a plurality of additional raised lines 132a may be formed. Also, there may be more than two rows of semiconductor chips extending in the lengthwise direction of the package substrate 110.

Continuing with FIG. 5, the molding material 135 may be injected into the cavity of the mold. The cavity of the mold may have a main part that corresponds to the base portion 130 of the molding member 134 described above, and grooves that correspond to the warpage-preventing portion 132 of the molding member 134 described above. When the cavity including the grooves is fully filled with the molding material 135, the molding material 135 may include the first warpage-preventing portion 132, including first lines 132a extending along the long side surface 112 of the package substrate 110, and second lines 132b extending along the short side surface 114 of the package substrate 110. In certain embodiments, the molding material 135 may include an insulating material such as, for example, an epoxy molding compound (EMC). The molding material in this state may be referred to as an initial molding structure, or a pre-annealed molding structure or member.

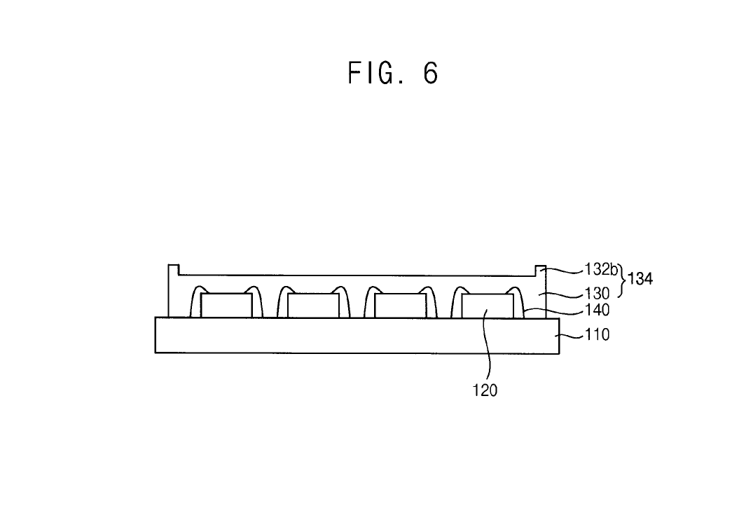

Referring to FIG. 6, after removing the mold, the annealing process may be performed on the molding material 135 to form the molding member 134 including the base portion 130 and the first warpage-preventing portion 132. In one embodiment, the molding material 135 is thermally treated. The thermally treated molding material 135 may be annealed to form the molding member 134. After annealing, the molding member 134 may be referred to as a final molding structure, or a post-annealed molding structure or member. The warpage preventing portions described herein may refer, for example, to the raised portions of either the pre-annealed molding structure or the post-annealed molding structure, depending on the context in which it is used.

During the annealing process, the molding material 135 having the thermal expansion coefficient higher than the thermal expansion coefficient of the package substrate 110 may be more contracted relatively than the package substrate 110. However, the first warpage-preventing portion 132, for example, including one or more raised lines 132a and/or 132b that may form support beams, may suppress the contraction of the molding material 135 along the long side surface 112 and/or short side surface 114 of the package substrate 110. Therefore, the package substrate 110 may not be downwardly warped, or may be less downwardly warped than if the warpage-preventing portion 132 had not been used. Similarly, if a molding material 135 is used that has a thermal expansion coefficient lower than the thermal expansion coefficient of the package substrate 110, then upward warping of the package substrate may be prevented or reduced.

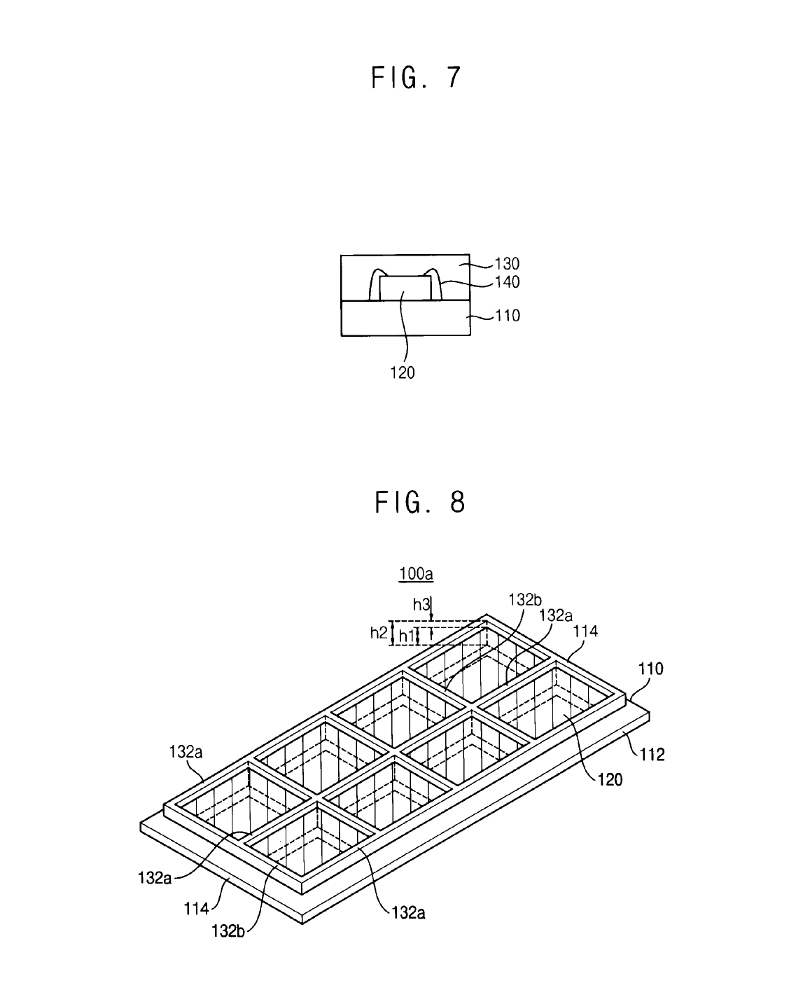

Referring to FIG. 7, the package substrate 110 may be cut along the scribe lane of the package substrate 110 to singulate the semiconductor chips 120. The first warpage-preventing lines 132a and second warpage-preventing lines 132b in the scribe lane of the package substrate 110 may also be removed by the cutting process. Thus, the semiconductor packages resulting from the semiconductor package structure 100 may not include the raised portions of the molding member 134, and thus may not include the first or second warpage-preventing lines 132a or 132b. As such, the warpage-preventing portion 132 may not be part the structure of the final semiconductor packages formed from the semiconductor package structure 100.

External terminals such as solder balls may then be mounted on the lower surface of the package substrate 110. Alternatively, the external terminals may be mounted on the lower surface of the package substrate 110 before the cutting process.

According to this example embodiment, a molding member may include the warpage-preventing portion including one or more raised lines (e.g., having bar shapes) so that the package substrate may not be warped along the long side surface of the package substrate during the annealing process. Particularly, because the first warpage-preventing portion may be integrally formed with the molding member, it may not require additional processes for forming semiconductor devices using a warpage-preventing portion on a molding member. Further, the first and/or second warpage-preventing lines of the warpage-preventing portion may be removed by cutting the molding member so that other than using a different shaped mold (e.g., one having ridges), the manufacturing process for forming the final semiconductor package may not be otherwise affected.

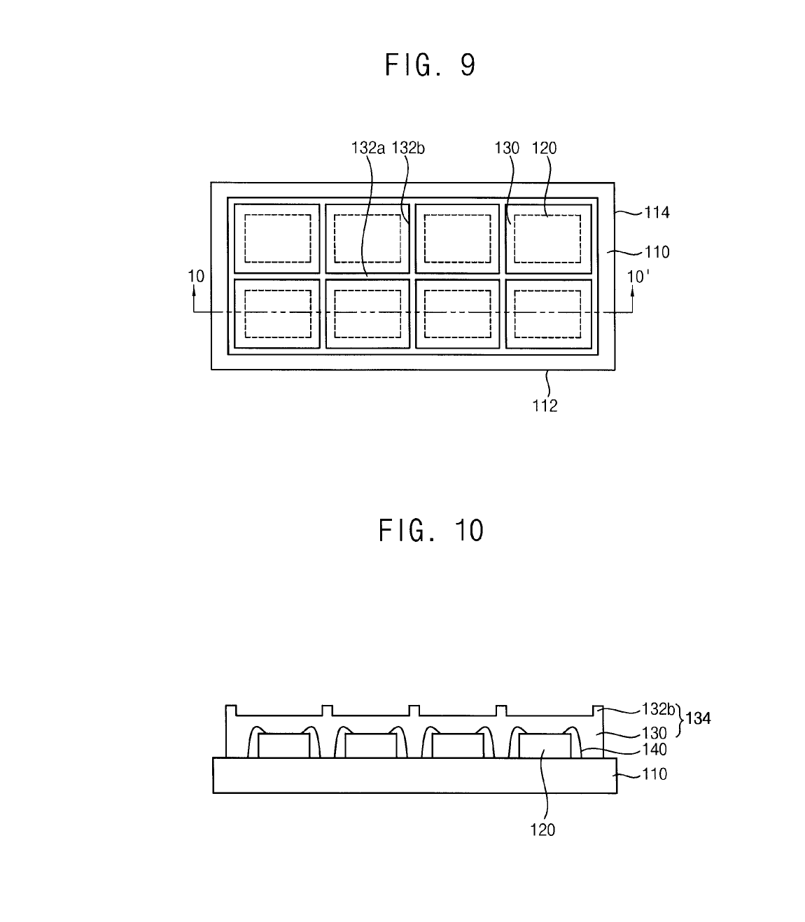

FIG. 8 is a perspective view illustrating a semiconductor package structure in accordance with example embodiments, FIG. 9 is an exemplary plan view illustrating the semiconductor package structure in FIG. 8, and FIG. 10 is an exemplary cross-sectional view taken along a line 10-10′ in FIG. 9.

A semiconductor package structure 100a of this example embodiment may include elements substantially the same as those of the semiconductor package structure 100 in FIG. 1 except for differences in the warpage-preventing portion. Thus, the same reference numerals may refer to the same elements and any further illustrations with respect to the same elements may be omitted herein for brevity.

Referring to FIGS. 8 to 11, a warpage-preventing portion of this example embodiment may further include additional second warpage-preventing lines 132b configured to prevent the package substrate 110 from being warped along the short side surface 114 of the package substrate 110. The second warpage-preventing lines 132b may be extended along the short side surface 114 of the package substrate 110. As shown in FIGS. 8-10, the first warpage-preventing lines 132a and the second warpage-preventing lines 132b may intersect each other in a cross shape so that the warpage-preventing portion may have a grid structure configured to surround each of the semiconductor chips 120.

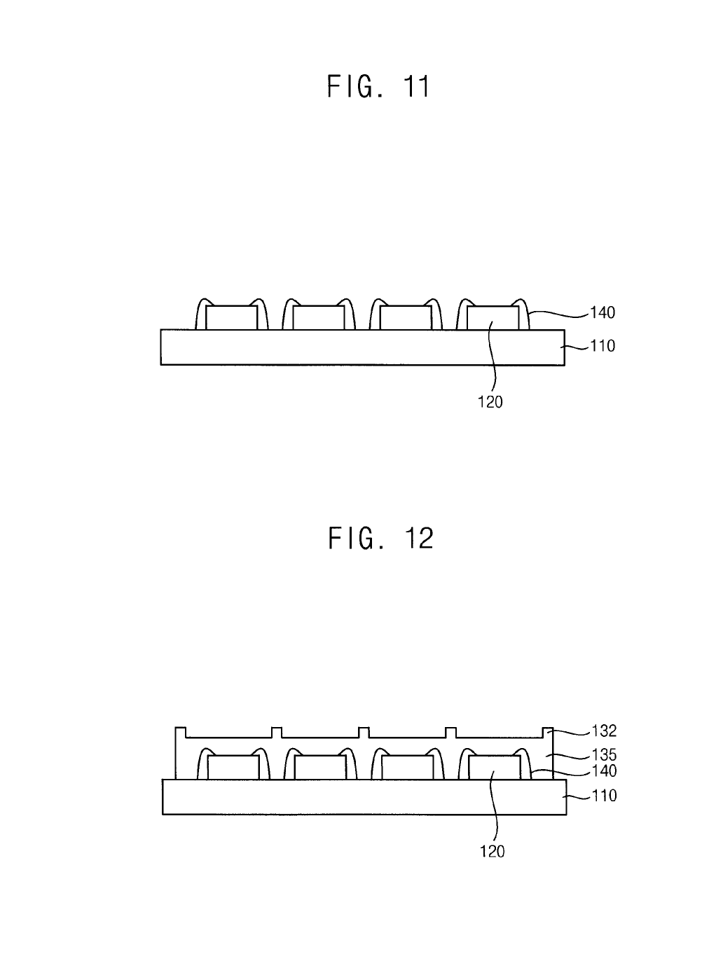

FIGS. 11 to 14 are cross-sectional views illustrating a method of manufacturing the semiconductor package using a semiconductor package structure such as shown in FIG. 9.

Referring to FIG. 11, the semiconductor chips 120 may be attached to the upper surface of the package substrate 110. The semiconductor chips 120 may be arranged by the substantially the same interval. Thus, the scribe lane of the package substrate 110 may be formed between the semiconductor chips 120.

The conductive wires 140 may be electrically connected between the semiconductor chips 120 and the package substrate 110. The conductive wires 140 may electrically connect the bonding pads of the semiconductor chips 120 with the conductive patterns of the package substrate 110. Alternatively, the semiconductor chips 120 may be electrically connected with the package substrate 110 using the conductive bumps.

Referring to FIG. 12, the package substrate 110 with the semiconductor chips 120 may be positioned in a cavity of a mold. The mold may include first grooves for forming the first warpage-preventing lines 132a and second grooves for forming the second warpage-preventing lines 132b. Thus, the first grooves may be formed on an upper surface of the cavity of the mold along the long side surface 112 of the package substrate 110. The second grooves may be formed on the upper surface of the cavity of the mold along the short side surface 114 of the package substrate 110.

The molding material 135 may be injected into the cavity of the mold. When the cavity, the first grooves and the second grooves are fully filled with the molding material 135, the molding material 135 may include a base portion, and may also include the first warpage-preventing lines 132a extended along the long side surface 112 of the package substrate 110, and the second warpage-preventing lines 132b extended along the short side surface 114 of the package substrate 110. The first warpage-preventing lines 132a and the second warpage-preventing lines 132b may intersect each other in a cross shape, for example, to form a grid pattern.

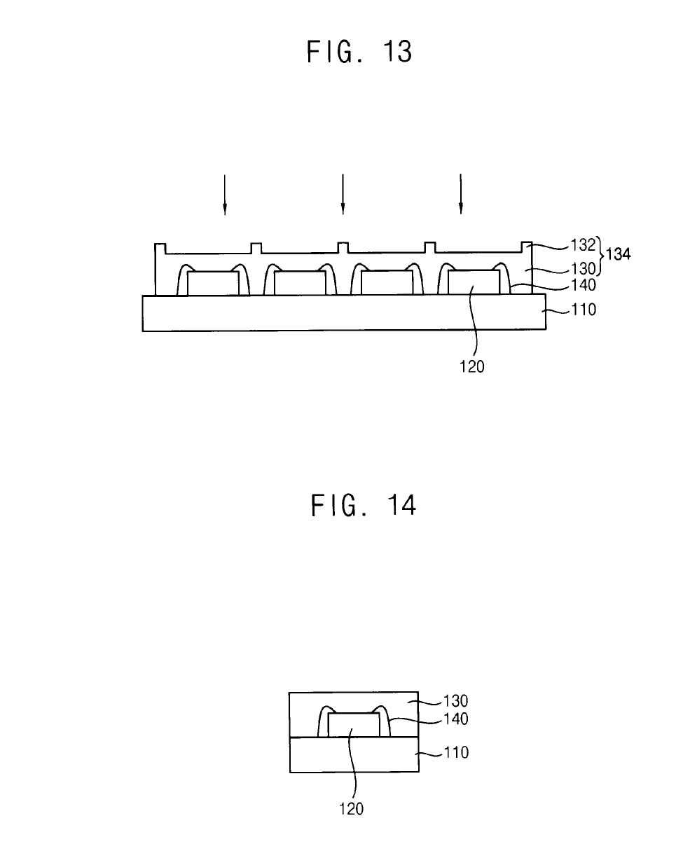

Referring to FIG. 13, the annealing process may be performed on the molding material 135 to form the molding member 134 including a base portion 130, the first warpage-preventing lines 132a and the second warpage-preventing lines 132b. The molding material 135 may be thermally treated. The thermally treated molding material 135 may be annealed to form the molding member 134.

During the annealing process, the molding material 135 having the thermal expansion coefficient higher than the thermal expansion coefficient of the package substrate 110 may be more contracted relatively than the package substrate 110. However, the first warpage-preventing lines 132a may suppress the contraction of the molding material 135 along the long side surface 112 of the package substrate 110. Further, the second warpage-preventing lines 132b may suppress the contraction of the molding material 135 along the short side surface 114 of the package substrate 110. Therefore, the package substrate 110 may not be downwardly warped, or warpage may be reduced.

Referring to FIG. 14, the package substrate 110 may be cut along the scribe lane of the package substrate 110 to singulate the semiconductor chips 120. The first warpage-preventing lines 132a and the second warpage-preventing lines 132b in the scribe lane of the package substrate 110 may also be removed by the cutting process. Thus, the semiconductor packages singulated from the semiconductor package structure 100a may not include the first warpage-preventing lines 132a or the second warpage-preventing lines 132b so that the first warpage-preventing lines 132a and the second warpage-preventing lines 132b do not increase the size of the structure of the final semiconductor packages formed from the semiconductor package structure 100a.

External terminals such as solder balls may be mounted on the lower surface of the package substrate 110. Alternatively, the external terminals may be mounted on the lower surface of the package substrate 110 before the cutting process.

According to this example embodiment, the molding member may include the first warpage-preventing lines and the second warpage-preventing lines so that the package substrate may not be warped along the long side surface and the short side surface of the package substrate during the annealing process. Particularly, because the first warpage-preventing lines and the second warpage-preventing lines may be integrally formed with the molding member, an additional process for forming the first warpage-preventing lines and the second warpage-preventing lines need not be performed. Further, the first warpage-preventing line and the second warpage-preventing line may be removed by cutting the molding member so that the first warpage-preventing line and the second warpage-preventing line do not increase the size or change the resulting the structure of the final semiconductor packages.

According to example embodiments, the molding member may include the warpage-preventing portion so that the package substrate may not be warped, or so that warpage may be reduced during the annealing process. Particularly, because the warpage-preventing portion may be integrally formed with the base portion of the molding member, an additional process for forming the warpage-preventing portion need not be performed. Further, the warpage-preventing portion may be removed by cutting the molding member so that the warpage-preventing portion is not included in a structure of the final semiconductor packages.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor package, the method comprising:
providing a package substrate;
arranging a plurality of semiconductor devices in an array pattern on an upper surface of the package substrate;
electrically connecting the plurality of semiconductor devices to the package substrate; and
forming a molding member on the upper surface of the package substrate to cover the semiconductor chips, the molding member including a warpage-preventing portion configured to prevent or reduce a warpage of the package substrate,
wherein the warpage-preventing portion is raised above a top surface of a base portion of the molding member.

2. The method of claim 1, wherein the warpage-preventing portion is formed along a boundary lane between the semiconductor devices.

3. The method of claim 1, wherein the base portion of the molding member is integrally formed with the warpage-preventing portion.

4. The method of claim 3, wherein the base portion of the molding member and the warpage-preventing portion are formed in a single process using a mold.

5. The method of claim 4, wherein the forming the molding member includes:
placing the mold over the package substrate;
filling the mold with a mold material;
removing the mold; and
performing a heating and annealing process on the mold material.

6. The method of claim 3, where the warpage-preventing portion includes one or more support beams formed at a top of the molding member.

7. The method of claim 6, wherein the warpage-preventing portion has a grid structure configured to surround each of the semiconductor devices.

8. The method of claim 1, wherein the package substrate extends lengthwise and widthwise, a length being longer than a width, and the warpage-preventing portion comprises at least a first warpage-preventing line extending in a lengthwise direction of the package substrate.

9. The method of claim 8, wherein the warpage-preventing portion further comprises at least a second warpage-preventing line extending in a widthwise direction of the package substrate.

10. The method of claim 1, further comprising providing conductive connecting members electrically connected between the package substrate and the semiconductor devices.

11. The method of claim 1, wherein the semiconductor devices are semiconductor chips.

12. The method of claim 1, further comprising singulating the semiconductor devices from each other to form a plurality of individual semiconductor packages,
wherein the warpage-preventing portion is formed at scribe regions of the package substrate, and
the singulating the semiconductor devices includes cutting the package substrate and molding member at the scribe regions to prevent the warpage-preventing portion from being included in the molding member of the individual semiconductor packages.

13. A method of manufacturing a semiconductor package, the method comprising:
arranging a plurality of semiconductor devices on an upper surface of a package substrate;
electrically connecting the semiconductor devices with the package substrate;
coating a molding material on the upper surface of the package substrate, the molding material including a warpage-preventing portion configured to prevent or reduce a warpage of the package substrate;
annealing the molding material to form a molding member configured to cover the semiconductor devices;
cutting the molding member along a scribe lane between the semiconductor devices; and
removing the warpage-preventing portion in the process.

14. The method of claim 13, wherein the warpage-preventing portion includes at least a first raised portion raised above a top surface of a base portion of the molding material.

15. The method of claim 14, wherein the coating the molding material comprises forming the first raised portion in a lengthwise direction of the substrate.

16. The method of claim 15, wherein the coating the molding material further comprises forming at least a second raised portion in a widthwise direction of the package substrate.

17. The method of claim 14, wherein the warpage-preventing portion is integrally formed with the base portion to form the molding member.

18. A method of manufacturing a semiconductor device, the method comprising:
providing a package substrate;
placing a plurality of semiconductor devices in an array pattern on the package substrate to form a semiconductor device structure;
electrically connecting the plurality of semiconductor devices to the package substrate;
forming a molding member on the package substrate, the molding member including a base portion extending to a first height above a top surface of the substrate, and at least a first raised portion extending above a top of the base portion to a second height higher than the first height, the base portion being integrally formed with the first raised portion; and
singulating the plurality of semiconductor devices from each other to form a plurality of individual semiconductor packages.

19. The method of claim 18, wherein the first raised portion forms a support beam and is formed at a scribe region of the semiconductor device structure between semiconductor devices, and the singulating the plurality of semiconductor devices includes cutting the molding member along the scribe region between the semiconductor devices, and removing at least the first raised portion in the process.

20. The method of claim 18, wherein the first raised portion is a part of a warpage-preventing portion configured to prevent or reduce warping during forming the plurality of semiconductor devices.
